(19) United States
(12) Patent Application Publication
(10) Pub. No.: US 2024/0258439 A1
(43) Pub. Date: Aug. 1, 2024

(54) SCHOTTKY DIODE AND METHOD OF FABRICATION THEREOF

(71) Applicant: Taiwan Semiconductor Manufacturing Company, Ltd., Hsinchu (TW)

(72) Inventors: Cheng-Wei WU, Taichung City (TW); Yu-Chi LIAO, Hsinchu City (TW)

(21) Appl. No.: 18/161,555

(22) Filed: Jan. 30, 2023

(51) Int. Cl. H01L 29/872; H01L 21/302; H01L 29/06; H01L 29/66

(52) U.S. Cl. CPC H01L 29/872; H01L 21/302; H01L 29/0649; H01L 29/0692; H01L 29/66143

(57) ABSTRACT

A method of forming a semiconductor device includes providing a first isolation feature in a substrate, where the first isolation feature defines and isolates a cathode region of a Schottky barrier diode (SBD) from an anode region of the SBD. In some embodiments, the method further includes forming a patterned resist protective oxide (RPO) layer over the first isolation feature. Thereafter, the method further includes forming a first metal contact that extends through the patterned RPO layer and extends into the first isolation feature.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

One particular semiconductor device of interest is the Schottky barrier diode, which exhibits a low forward voltage drop, very fast switching speeds, and low power consumption. Schottky barrier diodes include a metal layer in contact with a semiconductor surface. As an example, a Schottky diode may include a metal silicide layer in contact with a well region, such as an N-well region, of a silicon substrate. While Schottky diodes have a number of advantages, Schottky diodes have a relatively low breakdown voltage (e.g., as compared to P-N junction diodes). As a result, the operation voltage of Schottky diodes is also relatively low. Thus, existing Schottky diodes have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method of fabricating a semiconductor device 200, in accordance with some embodiments;

FIGS. 2B, 3B, 4B, 5B, 6B, 7B, 8B, 9B provide cross-sectional views of the semiconductor device 200 at various stages of fabrication according to one or more steps of the method of FIG. 1, in accordance with some embodiments;

FIGS. 2A, 3A, 4A, 5A, 6A, 7A, 8A, 9A provide top-down views of the semiconductor device 200 at various stages of fabrication according to one or more steps of the method of FIG. 1, in accordance with some embodiments; and

FIGS. 10A, 10B, 10C, 10D, 10E provide an enlarged view of a portion of the semiconductor device 200 as shown in FIG. 8B, at different stages of processing, in accordance with some embodiments.

### DETAILED DESCRIPTION

The following disclosure provides many different embodiments, or examples, for implementing different features of the provided subject matter. Specific examples of components and arrangements are described below to simplify the present disclosure.

These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

As noted above, a particular semiconductor device of interest is the Schottky barrier diode, which exhibits a low forward voltage drop, very fast switching speeds, and low power consumption. Schottky barrier diodes include a metal layer in contact with a semiconductor surface. By way of example, a Schottky diode may include a metal silicide layer in contact with a well region, such as an N-well region, of a silicon substrate. While Schottky diodes have a number of advantages, Schottky diodes have a relatively low breakdown voltage (e.g., as compared to P-N junction diodes). As a result, the operation voltage of Schottky diodes is also relatively low. Thus, existing Schottky diodes have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include device structures and methods for fabrication of Schottky barrier diodes that address various existing challenges, as discussed above. The methods and Schottky diodes described herein, in some embodiments, are designed to have a high breakdown voltage, which provides for an increased operation voltage. Such devices may thus be suitable for a wider array of applications. In some embodiments, the higher breakdown voltage is achieved by adding one or more contact features into an isolation region, such as a shallow trench isolation (STI) region, between an anode and a cathode of the Schottky diode. The one or more contact features formed in the isolation region, which may be electrically coupled to the cathode of the Schottky diode, can be used to enlarge a depletion region and thereby increase a breakdown voltage of the device.

In various examples, formation of the one or more contact features in the isolation region is performed by using a resist protective oxide (RPO) film formed over the isolation region. In some cases, the RPO film may include a multi-layer dielectric stack, such as an oxide layer/nitride layer/oxide layer stack. As an example, the oxide layers may include silicon dioxide or other suitable oxide, and the nitride layer may include silicon nitride, silicon oxynitride, or other suitable nitride layer. In some cases, the nitride layer is used as an etch stop layer during a three-step contact etch process to form the one or more contact features in the isolation region. A contact depth of the one or more contact features formed in the isolation region may in various embodiments, be in a range of between about 0.3-0.5 times a depth of the isolation region in order to provide a better depletion region boundary. Further, a minimum distance between the one or more contact features and a boundary of the isolation region may be greater than about 100 Angstroms in order to avoid oxide breakdown.

In view of these features and advantages, the Schottky barrier diodes disclosed herein may achieve desired performance and reliability metrics. Additional embodiments and advantages are discussed below and/or will be evident to those skilled in the art in possession of this disclosure.

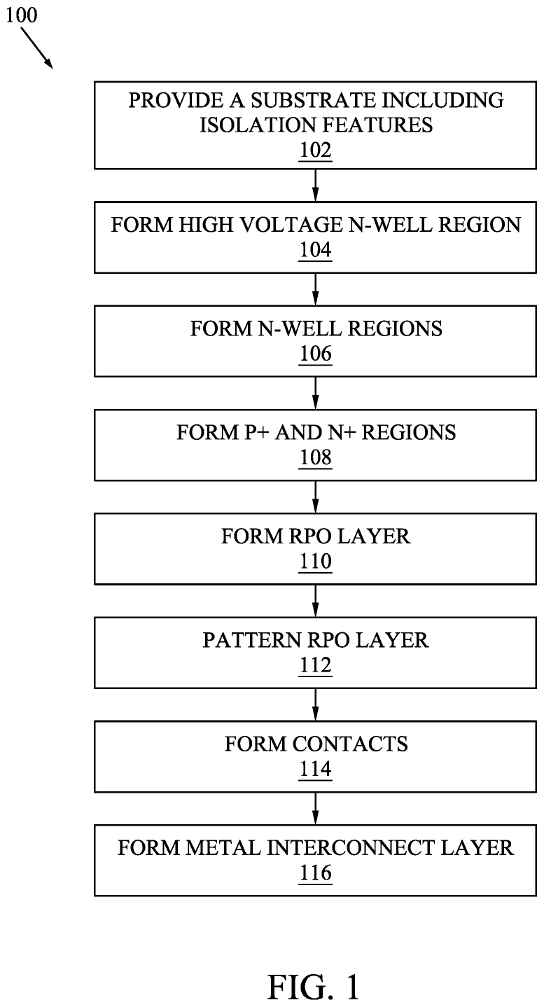

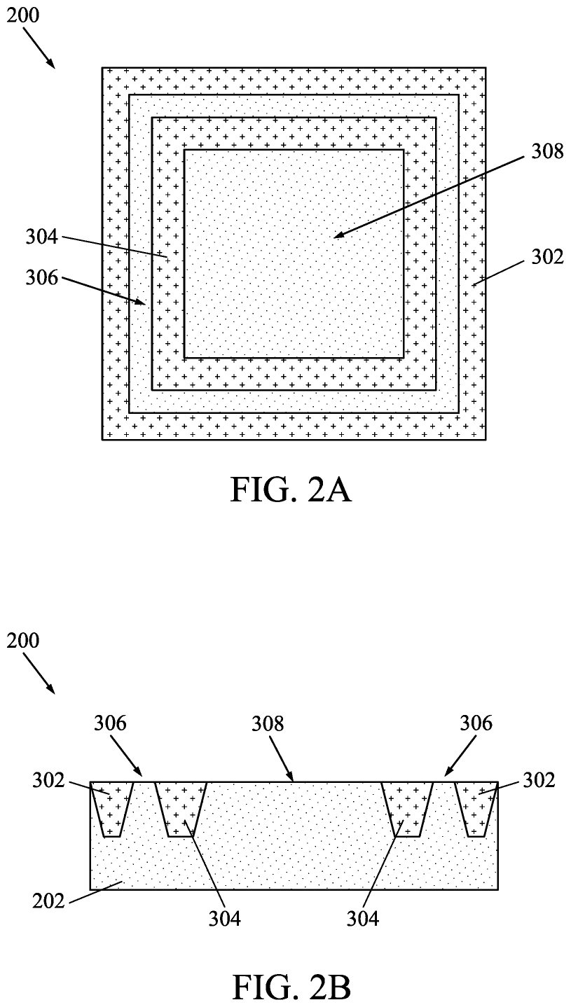

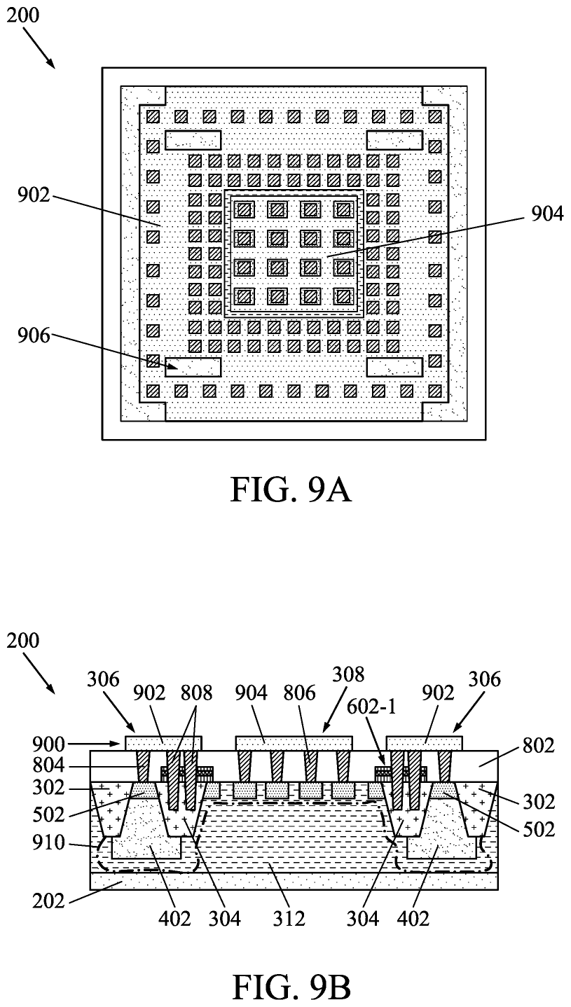

Referring now to FIG. 1, illustrated is a method 100 of fabricating a semiconductor device 200 including a Schottky barrier diode, in accordance with one or more embodiments. The method 100 is discussed below with reference to FIGS. 2B-9B, which provide cross-section views of the semiconductor device 200, and with reference to FIGS. 2A-9A, which provide top-down views of the semiconductor device 200, at various stages of fabrication, according to one or more steps of the method 100. It is understood that the method 100 includes steps having features of a complementary metal-oxide-semiconductor (CMOS) technology process flow and thus, are only described briefly herein. Also, additional steps may be performed before, after, and/or during the method 100, and some process steps may be replaced or eliminated, without departing from the scope of the present disclosure.

In addition, the semiconductor device 200 may include various other devices and features, including other types of devices such as planar MOSFETs, FinFETs, GAA transistors, strained-semiconductor devices, SOI devices, charge-coupled devices, CMOS sensors, photodiodes, other optical devices, bipolar junction transistors, resistors, capacitors, inductors, diodes, fuses, memory devices such as static random access memory (SRAM) devices, I/O transistors, other logic devices and/or circuits, etc., but is simplified for a better understanding of the inventive concepts of the present disclosure. In some embodiments, the semiconductor device 200 includes a plurality of semiconductor devices (e.g., transistors), including P-type transistors, N-type transistors, etc., which may be interconnected. Moreover, it is noted that the process steps of method 100, including any descriptions given with reference to the figures are merely exemplary and are not intended to be limiting beyond what is specifically recited in the claims that follow.

The method 100 begins at block 102 where a substrate including isolation features is provided. Referring to the example of FIGS. 2A/2B, in an embodiment of block 102, a substrate 202 is provided. In some embodiments, the substrate 202 may be a semiconductor substrate such as a silicon substrate. The substrate 202 may include various layers, including conductive or insulating layers formed on a semiconductor substrate. The substrate 202 may include various doping configurations depending on design requirements as is known in the art. The substrate 202 may also include other semiconductors such as germanium, silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) structure, and/or have other suitable enhancement features.

For purposes of the discussion that follows, the substrate 202 is a P-doped silicon substrate. P-type dopants that the substrate 202 are doped with include boron, gallium, indium, other suitable P-type dopants, or combinations thereof. Because the depicted semiconductor device 200 includes a P-doped substrate, doping configurations described below should be read consistent with a P-doped substrate. The semiconductor device 200 may alternatively include an N-doped substrate, in which case, the doping configurations described below should be read consistent with an N-doped substrate (e.g., read with doping configurations having an opposite conductivity). N-type dopants that the substrate 202 can be doped with include phosphorus, arsenic, other suitable N-type dopants, or combinations thereof.

In accordance with the discussion that follows, one or more Schottky barrier diodes (SBDs) may be formed on the substrate 202. Further, in some embodiments, other devices and/or circuits (e.g., such as logic devices and/or circuits) may also be formed on the substrate 202. In at least some examples, such other devices and/or circuits may include planar MOSFETs, FinFETs, GAA transistors, CMOS transistors, strained-semiconductor devices, SOI devices, bipolar junction transistors, resistors, capacitors, inductors, diodes, fuses, memory devices such as SRAM devices, I/O transistors, and/or other logic devices and/or circuits. In some cases, one or more of the Schottky barrier diodes may be coupled to one or more of the other devices and/or circuits (e.g., such as logic devices and/or circuits), for example, to collectively define various types of circuits such as an RFID circuit, a circuit for wirelessly charging mobile devices, a voltage doubler RF-to-DC rectifier circuit, or other type of circuit.

In a further embodiment of block 102, and still referring to the example of FIGS. 2A/2B, isolation features 302, 304 are formed in the substrate 202. The isolation features 302, 304 are formed in the substrate 202 to isolate various active (OD) regions of the substrate 202. The isolation features 302, 304 may also isolate the semiconductor device 200 from other devices (not shown). In some examples, the isolation feature 302 may isolate one Schottky barrier diode from another Schottky barrier diode or from other devices formed on the substrate 202, while the isolation feature 304 serves to define and isolate a cathode region 306 of a Schottky barrier diode from an anode region 308 of the Schottky barrier diode. In the cross-section view of FIG. 2B, the cathode region 306 is illustrated as being formed on either side of the anode region 308. In the top-down view of FIG. 2A, the cathode region 306 is illustrated as being formed surrounding the anode region 308. In some cases, the isolation feature 304 may be described as providing an isolation structure or guard ring structure surrounding the anode region 308, and the isolation feature 302 may be described as providing an isolation structure or guard ring structure surrounding the Schottky barrier diode (e.g., the semiconductor device 200).

In the depicted embodiment, the isolation features 302, 304 are shallow trench isolation (STI) features. Alternatively, the isolation features 302, 304 may include local oxidation of silicon (LOCOS) features or other suitable isolation feature. The isolation features 302, 304 may be composed of silicon oxide, silicon nitride, silicon oxynitride, fluorine-doped silicate glass (FSG), a low-K dielectric, combinations thereof, and/or other suitable material known in the art. The isolation features 302, 304 are formed by a suitable process. As one example, forming STI features includes a photolithography process, etching trenches in the substrate 202 (e.g., by using a dry etching and/or wet etching), and filling the trenches (e.g., by using a chemical vapor deposition process) with one or more dielectric materials. For example, the filled trenches may include a multi-layer structure such as a thermal oxide liner layer filled with silicon nitride or silicon oxide. In another example, the STI features may be formed using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with oxide, using chemical mechanical polishing (CMP) processing to etch back and planarize, and using a nitride stripping process to remove the silicon nitride.

The method 100 proceeds to block 104 where a high voltage N-well region is formed. Referring to the example of FIGS. 2A/2B and 3A/3B, in an embodiment of block 104, high voltage N-well (HVNW) region 312 is formed in the substrate 202 beneath the isolation features 302. In an embodiment of block 104, a photolithography process is performed to define a patterned resist layer through which an ion implantation process is subsequently performed to form the HVNW region 312. As part of the photolithography process, a photoresist layer is initially deposited over the semiconductor device 200 (e.g., by spin-on coating), after which one or more other photolithography processing steps may be performed such as soft baking, mask aligning, exposure, post-exposure baking, developing, rinsing, drying (e.g., spin-drying and/or hard baking), other suitable photolithography processing steps, and/or combinations thereof. As a result of the photolithography process, the patterned resist layer is formed. In an embodiment, the patterned resist layer substantially covers portions of the substrate 202 within which a Schottky barrier diode (e.g., the semiconductor device 200) is not being formed. In an embodiment, the patterned resist layer provides an opening through which the ion implantation process is subsequently performed to form the HVNW region 312.

In a further embodiment of block 104, the HVNW region 312 is implanted within the substrate 202, using an ion implantation process, through the opening in the patterned resist layer. In an example, the HVNW region 312 is implanted into the cathode region 306 and the anode region 308, including through the isolation features 302, 304 and into the substrate 202 such that the HVNW region 312 extends from the top surface of the substrate 202 (or from the top surface of the isolation features 302, 304) a distance “D1” into the substrate 202. In some embodiments, the distance D1 that the HVNW region 312 extends into the substrate 202 is in a range of about 3 μm to about 4 μm. In some embodiments, a doping concentration of the HVNW region 312 is about 1×10¹⁶ atoms/cm³ to about 1×10¹⁷ atoms/cm³. The HVNW region 312 is formed by implanting the substrate 202 with an N-type dopant, such as phosphorous or arsenic, and subjecting the HVNW region 312 to an annealing process, such as a rapid thermal anneal or laser anneal. Alternatively, the HVNW region 312 is formed by another suitable process, such as a diffusion process. After formation of the HVNW region 312, the patterned resist layer is removed (e.g., using a solvent or ashing process).

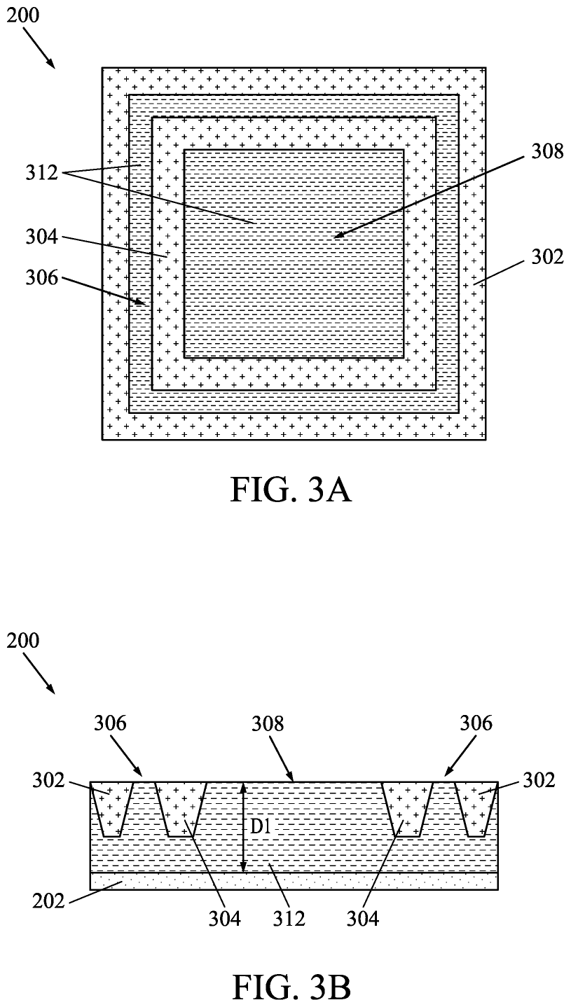

The method 100 proceeds to block 106 where N-well regions are formed. Referring to the example of FIGS. 3A/3B and 4A/4B, in an embodiment of block 106, N-well regions 402 are formed in the cathode region 306 of the substrate 202. In various embodiments, a cathode of the Schottky barrier diode is defined in the cathode region 306 (e.g., within the N-well region 402), and an anode of the Schottky barrier diode is defined in the anode region 308 (e.g., within the HVNW region 312). The cathode region 306 is separated from the anode region 308 by the isolation structure 304, as discussed above.

In an embodiment of block 106, a photolithography process is performed to define a patterned resist layer through which an ion implantation process is subsequently performed to form the N-well regions 402. The photolithography process and formation of the patterned resist layer may be similar to the method described above with respect to the HVNW region 312. In an embodiment, the patterned resist layer covers the HVNW region 312 in the anode region 308, while providing openings through which the ion implantation process is subsequently performed to form the N-well regions 402.

In a further embodiment of block 106, the N-well regions 402 are implanted within the substrate 202, using an ion implantation process, through openings in the patterned resist layer. In an example, the N-well regions 402 are implanted into the substrate 202 in the cathode region 306, and in some cases through portions of the isolation features 302, 304 on opposing sides of the cathode region 306, such that the N-well regions 402 extend from the top surface of the substrate 202 (or from the top surface of the isolation features 302, 304) a distance “D2” into the substrate 202. In some embodiments, the distance D2 that the N-well regions 402 extend into the substrate 202 is in a range of about 1 μm to about 2 μm. Thus, in the depicted embodiment, the N-well regions 402 extend a distance into the substrate 202 that is less than the depth of the HVNW region 312. Stated another way, and in various embodiments, the depth D2 of the N-well regions 402 is less than the depth D1 of the HVNW region 402. In some embodiments, a doping concentration of the N-well regions 402 is about 1×10¹⁷ atoms/cm³ to about 1×10¹⁸ atoms/cm³. In some cases, a doping concentration of the N-well regions 402 is greater than a doping concentration of the HVNW region 312. The N-well regions 402 are formed by implanting the substrate 202 with an N-type dopant, such as phosphorous or arsenic, and subjecting the N-well regions 402 to an annealing process, such as a rapid thermal anneal or laser anneal. Alternatively, the N-well regions 402 are formed by another suitable process, such as a diffusion process. After formation of the N-well regions 402, the patterned resist layer is removed (e.g., using a solvent or ashing process).

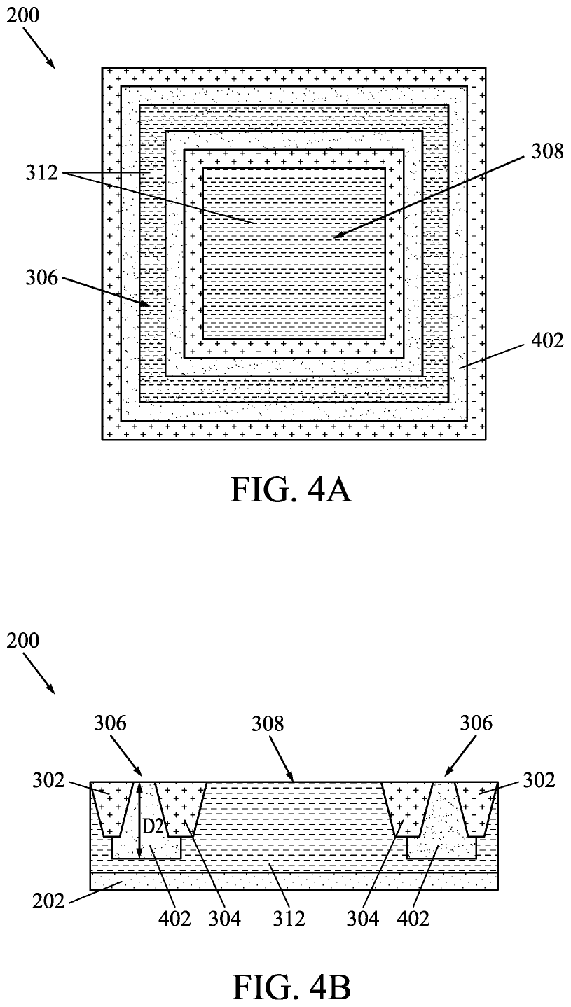

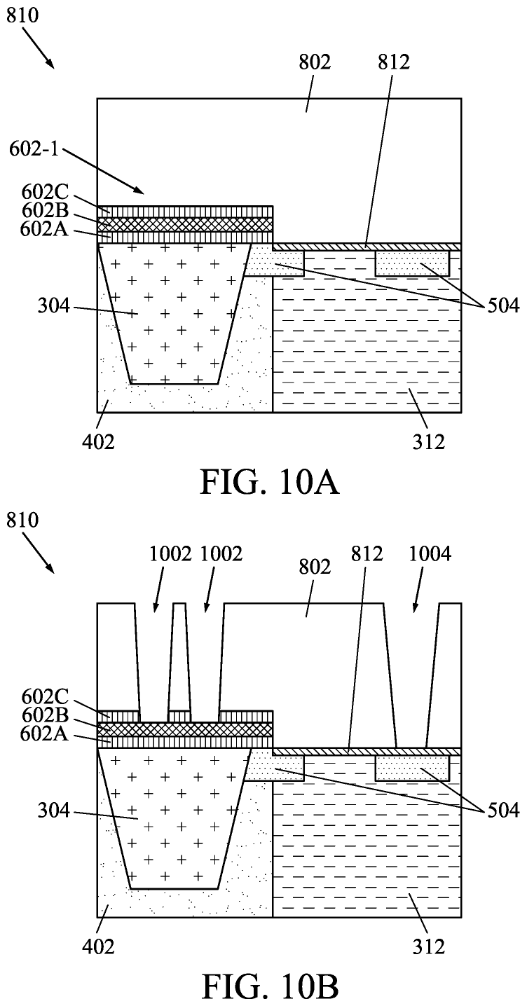

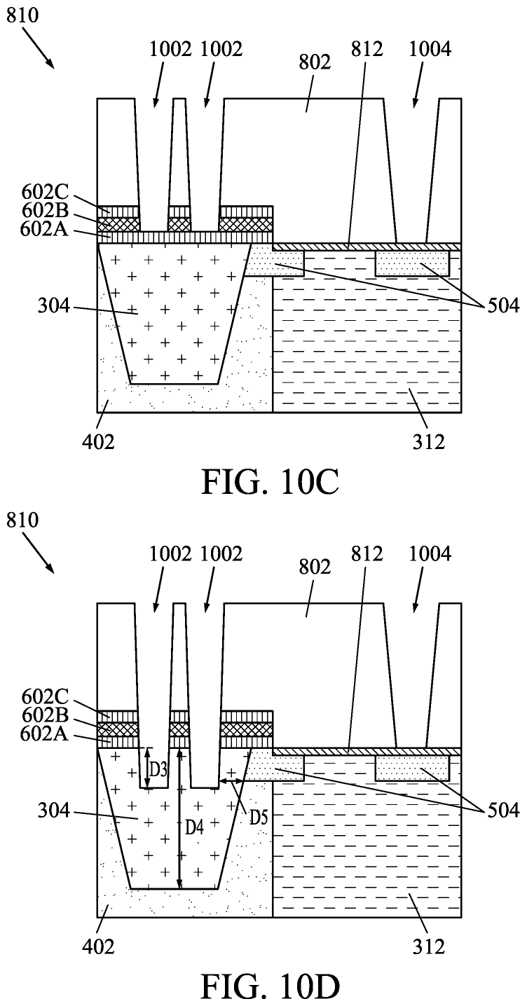

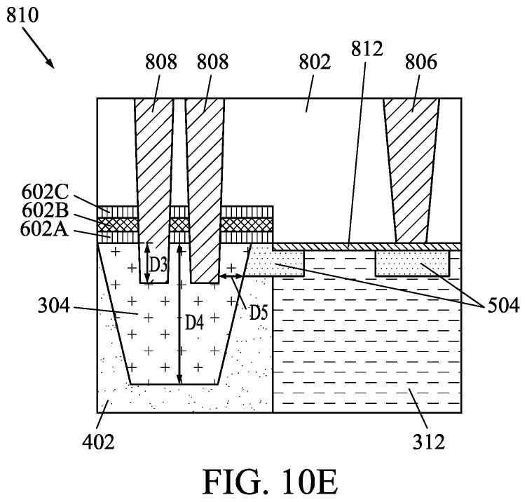

The method 100 proceeds to block 108 where P+ and N+ regions are formed. Referring to the example of FIGS. 4A/4B and 5A/5B, in an embodiment of block 108, N+ regions 502 are formed in the N-well regions 402 of the substrate 202 within the cathode region 306, and P+ regions 504 are formed in the HVNW region 312 of the substrate 202 within the anode region 308. In various embodiments, contact to the cathode of the Schottky barrier diode may be provided by a metal silicide layer (e.g., such as cobalt silicide or nickel silicide) in contact with the N+ regions 502, providing a low resistance (ohmic) contact thereto. In some examples, contact to the anode of the Schottky barrier diode may be provided by a metal silicide layer (e.g., such as cobalt silicide or nickel silicide) in contact with the HVNW region 312 between adjacent P+ regions 504 within the anode region 308 (e.g., such as the metal silicide layer 812 shown in FIGS. 10A-10E). In some cases, the metal silicide layer that contacts the HVNW region 312 within the anode region 308 may also contact the P+ regions 504 (e.g., as also shown in FIGS. 10A-10E). Thus, in some embodiments, the HVNW region 312 may be electrically coupled to the metal silicide layer, as well as to a metal contact overlying the metal silicide layer, through the P+ regions 504. The P+ regions 504, and contact thereto, may be used in some embodiments to increase a voltage that the device 200 is able to withstand under reverse bias (e.g., reverse breakdown voltage). It is also noted that in some cases, the N+ regions 502 may be formed before the P+ regions 504. However, in other cases, the P+ regions 504 may be formed before the N+ regions 502.

In some examples, the N+ regions 502 are heavily doped with an N-type dopant, such as phosphorous or arsenic. In some embodiments, the N+ regions 502 may be formed by diffusion, ion implantation, doped epitaxial growth, or a combination thereof. As part of the process of forming the N+ regions 502, a photolithography process may be performed to define a patterned resist layer through which an ion implantation process is subsequently performed to form the N+ regions 502. The photolithography process and formation of the patterned resist layer may be similar to the method described above. In some embodiments, after forming the patterned resist layer, the N+ regions 502 are implanted within the substrate 202, using an ion implantation process, through openings in the patterned resist layer. In some embodiments, a doping concentration of the N+ regions 502 is about 1×10¹⁸ atoms/cm³ to about 1×10²⁰ atoms/cm³. The N+ regions 502 may be formed by implanting the substrate 202 with an N-type dopant, such as such as phosphorous, arsenic, antimony, other suitable N-type dopants, or combinations thereof, and subjecting the N+ regions 502 to an annealing process, such as a rapid thermal anneal or laser anneal. Alternatively, the N+ regions 502 may be formed by another suitable process, such as a diffusion process. After formation of the N+ regions 502, the patterned resist layer is removed (e.g., using a solvent or ashing process).

In some examples, the P+ regions 504 are heavily doped with a P-type dopant, such as boron. In some embodiments, the P+ regions 504 may be formed by diffusion, ion implantation, doped epitaxial growth, or a combination thereof. As part of the process of forming the P+ regions 504, a photolithography process may be performed to define a patterned resist layer through which an ion implantation process is subsequently performed to form the P+ regions 504. The photolithography process and formation of the patterned resist layer may be similar to the method described above. In some embodiments, after forming the patterned resist layer, the P+ regions 504 are implanted within the substrate 202, using an ion implantation process, through openings in the patterned resist layer. In some embodiments, a doping concentration of the P+ regions 504 is about 1×10¹⁸ atoms/cm³ to about 1×10²⁰ atoms/cm³. The P+ regions 504 may be formed by implanting the substrate 202 with a P-type dopant, such as boron, gallium, indium, other suitable P-type dopants, or combinations thereof, and subjecting the P+ regions 504 to an annealing process, such as a rapid thermal anneal or laser anneal. Alternatively, the P+ regions 504 may be formed by another suitable process, such as a diffusion process. After formation of the P+ regions 504, the patterned resist layer is removed (e.g., using a solvent or ashing process).

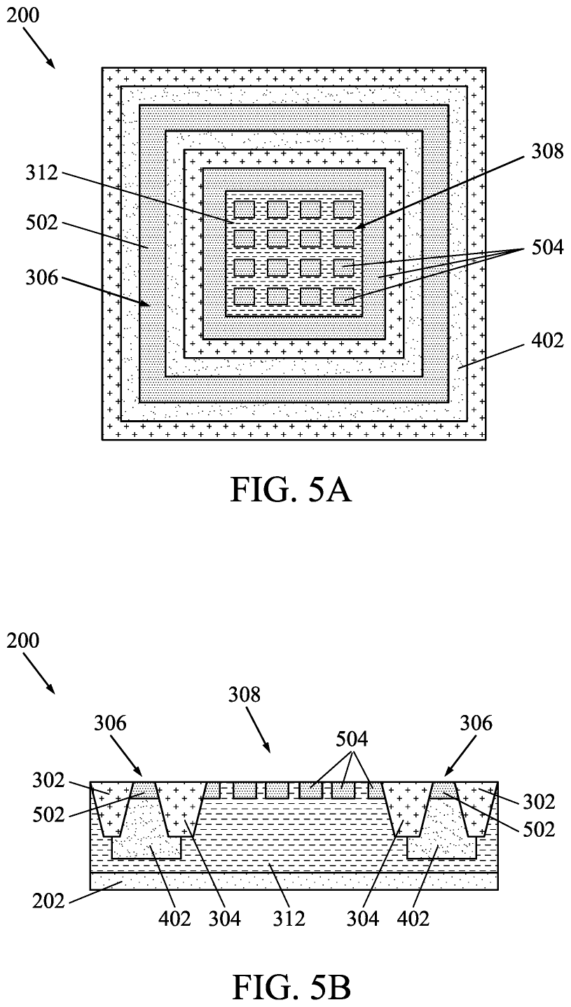

The method 100 proceeds to block 110 where a resist protective oxide (RPO) layer is formed. Referring to the example of FIGS. 5A/5B and 6A/6B, in an embodiment of block 110, an RPO layer 602 is formed over the substrate 202. As shown, the RPO layer 602 is formed over a top surface of the semiconductor device 200, including over the cathode region 306, the anode region 308, and the isolation features 302, 304. In some cases, the RPO film may include a multi-layer dielectric stack including an oxide layer 602A, a nitride layer 602B formed over the oxide layer 602A, and an oxide layer 602C formed over the nitride layer 602B. As an example, the oxide layers 602A, 602C may include silicon dioxide or other suitable oxide, and the nitride layer 602B may include silicon nitride, silicon oxynitride, or other suitable nitride layer. In some cases, the nitride layer 602B is used as an etch stop layer during a subsequent three-step contact etch process to form one or more contact features in the isolation region, as discussed in more detail below. Each of the oxide layer 602A, the nitride layer 602B, and the oxide layer 602C may be formed by CVD, ALD, PVD, thermal oxidation, combinations thereof, or other suitable processes. In some embodiments, the oxide layer 602A has a thickness equal to or greater than about 550 Angstroms, the nitride layer 602B has a thickness equal to or greater than about 150 Angstroms, and the oxide layer 602C has a thickness equal to or greater than about 10 Angstroms. Thus, in some examples, the oxide layer 602A may be thicker than each of the nitride layer 602B and the oxide layer 602C, and the nitride layer 602B may be thicker than the oxide layer 602C.

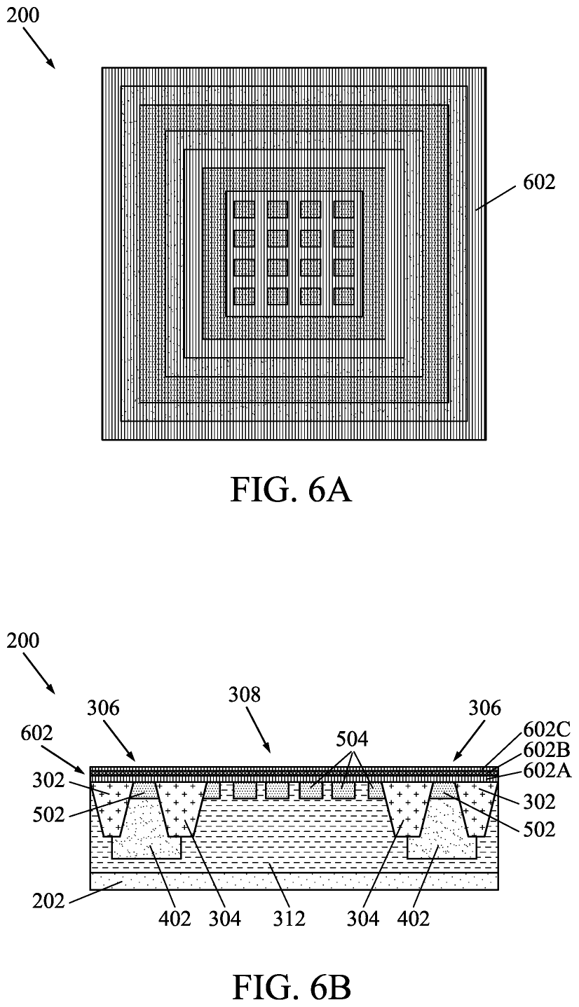

The method 100 proceeds to block 112 where the RPO layer is patterned. Referring to the example of FIGS. 6A/6B and 7A/7B, in an embodiment of block 112, the RPO layer 602 is patterned to form a patterned RPO layer 602-1. In some examples, patterning of the RPO layer may be performed using photolithography and etching processes. For instance, a photoresist layer may be initially deposited over the RPO layer 602, after which one or more other photolithography processing steps may be performed such as soft baking, mask aligning, exposure, post-exposure baking, developing, rinsing, drying (e.g., spin-drying and/or hard baking), other suitable photolithography processing steps, and/or combinations thereof. As a result of the photolithography process, a patterned photoresist layer is formed. Thereafter, an etching process (e.g., a wet etching process, a dry etching process, or a combination thereof) is performed, using the patterned photoresist layer as a masking layer, to etch exposed regions of the RPO layer 602 and thereby form the patterned RPO layer 602-1.

In various embodiments, the patterned RPO layer 602-1 has a width W (or critical dimension, CD) that is substantially equal to or greater than a width of a top surface of the isolation feature 304 (that isolates the cathode region 306 from the anode region 308). In some cases, the patterned RPO layer 602-1 is substantially aligned with the isolation feature 304 such that the patterned RPO layer 602-1 covers substantially all of the isolation feature 304. In other examples, the patterned RPO layer 602-1 may be offset with respect to the top surface of the isolation feature 304 such that the patterned RPO layer 602-1 covers at least part of a P+ region 504 that abuts the isolation feature 304, while still covering most (e.g., around 90%) of the isolation feature 304. In still other cases, for example when the width of the patterned RPO layer 602-1 is greater than the width of the top surface of the isolation feature 304, the patterned RPO layer 602-1 may cover substantially all of the isolation feature 304 as well as part of the P+ region 504 that abuts the isolation feature 304.

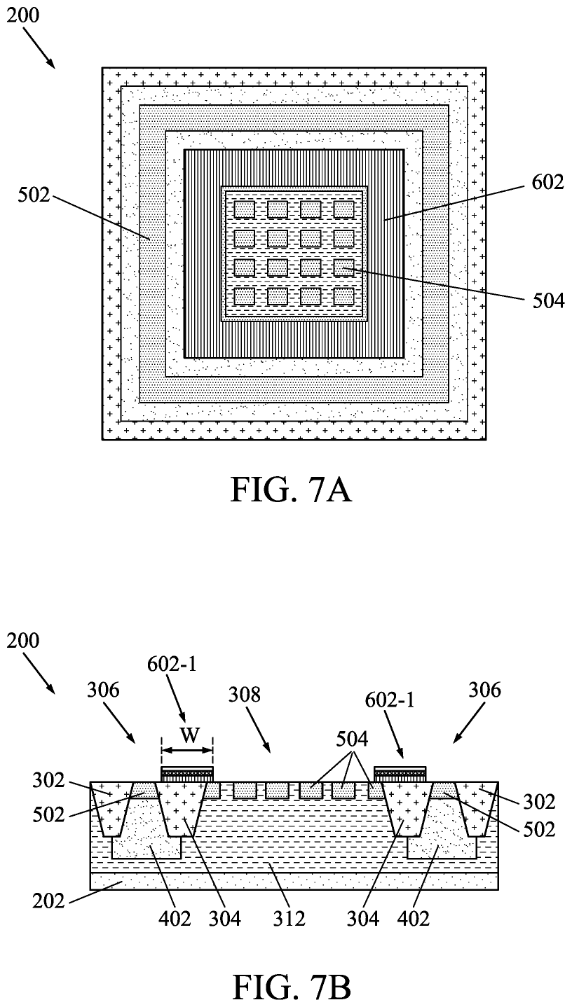

The method 100 proceeds to block 114 where contacts are formed. Referring to the example of FIGS. 7A/7B and 8A/8B, in an embodiment of block 114, a dielectric layer 802 is initially deposited over the substrate 202 including over the patterned RPO layer 602-1. By way of example, the dielectric layer 802 may include an inter-layer dielectric (ILD) layer that may include materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. The dielectric layer 802 may be deposited by a subatmospheric CVD (SACVD) process, a flowable CVD process, or other suitable deposition technique. In some embodiments, prior to forming the dielectric layer 802, metal silicide layers may be formed over the N+ regions 502 in the cathode region 306 and/or over the HVNW region 312/P+ regions 504 in the anode region 308, to provide a low-resistance (ohmic) contact thereto, an example of which is shown in FIGS. 10A-10E below. Thereafter, the dielectric layer 802 may be formed over the metal silicide layers. By way of example, such metal silicide layers may include nickel silicide (NiSi) or cobalt silicide (CoSi). Alternatively, in some embodiments, the metal silicide layers may include titanium silicide (TiSi), platinum silicide (PtSi), tantalum silicide (TaSi), other suitable metal silicide materials, or combinations thereof.

After depositing the dielectric layer 802, and in a further embodiment of block 114, the dielectric layer 802 is patterned to form openings in the dielectric layer 802 within which metal contacts will be formed. By way of example, the openings in the dielectric layer 802 may be formed by a suitable combination of lithographic patterning and etching (e.g., wet or dry etching) processes. In some cases, the openings provide access to the N+ regions 502 (or access to the metal silicide layer formed over the N+ regions 502) in the cathode region 306, the metal silicide layer over the P+ regions 504 (where the metal silicide layer that contacts the P+ regions 504 may also contact an adjacent HVNW region 312) in the anode region 308, and to the isolation feature 304 that interposes the cathode region 306 and the anode region 308. In the cathode region 306, the dielectric layer 802 is etched to form the openings that expose the N+ regions 502 (or the metal silicide layer formed over the N+ regions 502). Similarly, in the anode region 308, the dielectric layer 802 is etched to form the openings that expose the metal silicide layer over the P+ regions 504. To provide access to the isolation feature 304, however, both the dielectric layer 802 and the patterned RPO layer 602-1 are etched, as part of a three-step contact etch process, as described in more detail below with reference to FIGS. 10A-10E. Further, in accordance with embodiments of the present disclosure, the isolation feature 304 itself is partially etched such that the openings thereover extend from the dielectric layer 802, through the patterned RPO layer 602-1, and through part of the isolation feature 304.

After formation of the openings, and in a further embodiment of block 114, a glue or barrier layer (e.g., such as Ti, TiN, Ta, TaN, W, or other suitable material) may be formed within each of the opening. Thereafter, a metal layer may be formed on the glue or barrier layer within each of the openings. In some examples, the metal layer may include W, Cu, Co, Ru, Al, Rh, Mo, Ta, Ti, or other appropriate material. After deposition of the metal layer, a chemical mechanical planarization (CMP) process may be performed to remove excess material and planarize the top surface of the semiconductor device 200. As a result, a plurality of metal contacts are defined, including metal contacts 804 in contact with the N+ regions 502 (or in contact with the metal silicide layer over the N+ regions 502), metal contacts 806 in contact with the metal silicide layer over the P+ regions 504 (where the metal silicide layer that contacts the P+ regions 504 may also contact an adjacent HVNW region 312), and metal contacts 808 that extend into the isolation feature 304 to provide an improved depletion region boundary.

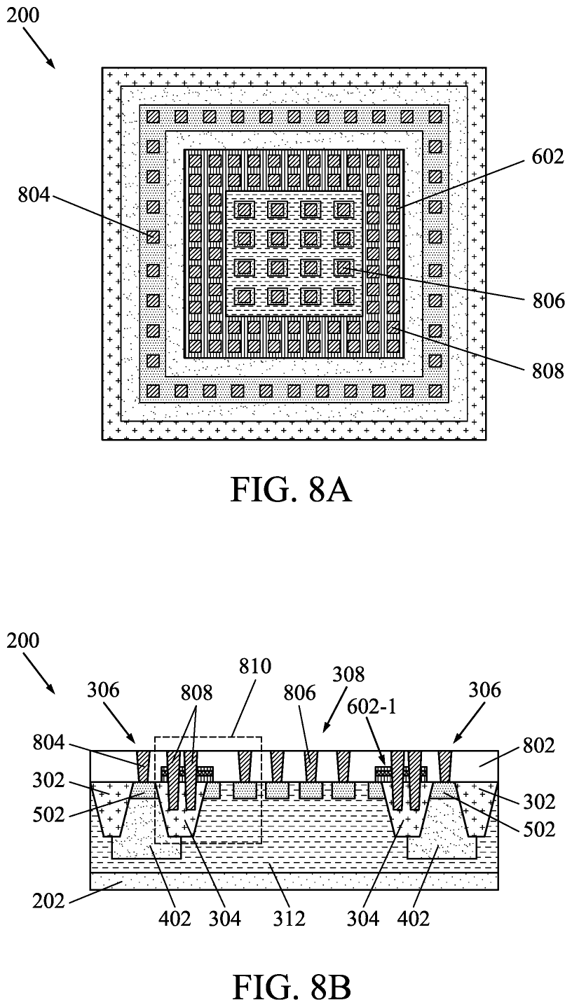

To elaborate on the formation of the contacts (block 114), reference is now made to FIGS. 10A-10E, which illustrate the three-step contact etch process used to etch through the patterned RPO layer 602-1 and through part of the isolation feature 304 in more detail. Each of the FIGS. 10A-10E provide an enlarged view of a portion 810 of the semiconductor device 200 as shown in FIG. 8B, at different stages of processing during the three-step contact etch process. FIG. 10A illustrates the portion 810 after deposition of the dielectric layer 802, but prior to patterning the dielectric layer 802 to form openings therein (e.g., prior to the three-step contact etch process). FIG. 10A also illustrates an exemplary metal silicide layer 812 that may be formed over the P+ regions 504 and over the HVNW region 312 in the anode region 308 prior to formation of the dielectric layer 802. As noted above, similar metal silicide layers may also be formed over the N+ regions 502.

FIG. 10B illustrates the portion 810 after a first step of the three-step contact etch process. In the first step (or first etching process) of the three-step contact etch process, the dielectric layer 802 and the oxide layer 602C of the patterned RPO layer 602-1 are etched to form openings 1002 over the isolation feature 304. The nitride layer 602B serves as an etch stop layer for the first etching process so that the first etching process stops on the nitride layer 602B. Also, as part of the first step of the three-step contact etch process, the dielectric layer 802 is etched to form openings 1004 over the P+ regions 504 in the anode region 308, where the openings 1004 expose the metal silicide layer 812 that may be formed over the P+ regions 504. While not shown, and still as part of the first step of the three-step contact etch process, the dielectric layer 802 may also be etched to form openings over the N+ regions 502 in the cathode region 306.

FIG. 10C illustrates the portion 810 after a second step of the three-step contact etch process. In the second step (or second etching process) of the three-step contact etch process, the nitride layer 602B of the patterned RPO layer 602-1 is etched to extend the openings 1002 over the isolation feature 304. In some embodiments, the second etching process stops on the oxide layer 602A. In various examples, the second step of the three-step contact etch process does not etch the metal silicide layer 812. Thus, after the second step of the three-step contact etch process, the openings 1004 over the P+ regions 504 in the anode region 308 may remain substantially the same and thus still expose the metal silicide layer 812. Similarly, after the second step of the three-step contact etch process, openings formed over the N+ regions 502 in the cathode region 306 may also remain substantially the same.

FIG. 10D illustrates the portion 810 after a third step of the three-step contact etch process. In the third step (or third etching process) of the three-step contact etch process, the oxide layer 602A of the patterned RPO layer 602-1 is etched, and a portion of the isolation feature 304 is etched, to further extend the openings 1002 over, and now extending into, the isolation feature 304. The three-step contact etch process provides for enhanced control of a depth by which the openings 1002 extend into the isolation feature 304. In one example, a depth ‘D3’ from a top surface of the isolation feature 304 to a bottom surface of the openings 1002 may be in a range of between about 0.3-0.5 times a total depth ‘D4’ of the isolation feature 304 in order to provide a better depletion region boundary. In addition, a minimum distance ‘D5’ between an edge of one of the openings 1002 and a boundary of the isolation feature 304 may be greater than about 100 Angstroms in order to avoid oxide breakdown. In various examples, the third step of the three-step contact etch process also does not etch the metal silicide layer 812. Thus, after the third step of the three-step contact etch process, the openings 1004 over the P+ regions 504 in the anode region 308 may remain substantially the same and thus still expose the metal silicide layer 812. Similarly, after the third step of the three-step contact etch process, openings formed over the N+ regions 502 in the cathode region 306 may also remain substantially the same.

FIG. 10E illustrates the portion 810 after formation of the openings (e.g., by the three-step contact etch process) and after deposition of a metal layer within the openings. As discussed above, a glue or barrier layer (e.g., such as Ti, TiN, Ta, TaN, W, or other suitable material) may be formed within each of the openings 1002, 1004. Thereafter, a metal layer may be formed on the glue or barrier layer within each of the openings. The metal layer may include W, Cu, Co, Ru, Al, Rh, Mo, Ta, Ti, or other appropriate material. After deposition of the metal layer, a CMP process may be performed to remove excess material and planarize the top surface of the semiconductor device 200. As a result of the metal layer deposition and CMP process, metal contacts 808 that extend into the isolation feature 304 are formed within the openings 1002 and metal contacts 806 in contact with the metal silicide layer 812 over the P+ regions 504 are formed within the openings 1004. Similarly, metal contacts 804 in contact with the N+ regions 502 may be formed within openings formed over the N+ regions 502. In various embodiments, the metal contacts 808 formed in the isolation feature 304, which may be electrically coupled to the cathode of the Schottky diode as described in more detail below, can be used to enlarge a depletion region and thereby increase a breakdown voltage of the device 200.

Since the metal contacts 808 are formed within the openings 1002, the geometry of the metal contacts 808 extending into the isolation feature 304 may be substantially the same as discussed above with respect to formation of the openings 1002. For example, a distance between the top surface of the isolation feature 304 and a bottom surface of the metal contacts 808 may be equal to the depth ‘D3’, discussed above, which may be in a range of between about 0.3-0.5 times the total depth ‘D4’ of the isolation feature 304. In addition, a distance between an edge of one of the metal contacts 808 and the boundary of the isolation feature 304 may be equal to the distance ‘D5’, discussed above, which is greater than about 100 Angstroms.

After formation of the contacts, as described above, the method 100 proceeds to block 116 where a metal interconnect layer is formed. Referring to the example of FIGS. 8A/8B and 9A/9B, in an embodiment of block 116, a metal interconnect layer 900 is formed. The metal interconnect layer 900, in some embodiments, may be a first metal layer (M1) of a multi-layer metal interconnect structure having a plurality of metal interconnect layers isolated from each other by ILD layers and interconnected by via structures disposed between adjacent metal interconnect layers. In the illustrated example, the metal interconnect layer 900 may include a metal layer 902 and a metal layer 904, which may be formed by a damascene and/or a dual damascene process. Optionally, in some cases, the metal layer 902 may include windows 906 (openings in the metal layer 902), in order to relieve stress in the metal layer 902. In some embodiments, the metal layers 902, 904 are formed of a conductive material such as copper, tungsten, silicide, and/or other suitable material. The metal layer 902, as shown, provides an electrical connection to the metal contacts 804 in contact with the N+ regions 502 (cathode of the device 200) as well as to the metal contacts 808 that extend into the isolation feature 304. The metal layer 904, as shown, provides an electrical connection to the metal contacts 806 in contact with the metal silicide layer 812 over the P+ regions 504. In some embodiments, the metal silicide layer 812 may further contact the HVNW region 312 (anode of the device 200), as previously noted. By electrically coupling the metal contacts 808 that extend into the isolation feature 304 to the cathode of the Schottky diode (e.g., by the metal layer 902), a voltage bias applied to the metal layer 902 can be used to enlarge a depletion region 910 and thereby increase a breakdown voltage of the semiconductor device 200 (e.g., such as when the semiconductor device 200 is reverse-biased).

The semiconductor device 200 may undergo further processing to form various features and regions known in the art. For example, subsequent processing may form various additional contacts/vias/lines and other multilayer interconnect features (e.g., metal layers and interlayer dielectrics) on the substrate, configured to connect the various features to form a functional circuit that may include one or more of the semiconductor devices 200. Generally, a multi-layer interconnect structure may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

Thus, the various embodiments described herein offer several advantages over the existing art. It will be understood that not all advantages have been necessarily discussed herein, no particular advantage is required for all embodiments, and other embodiments may offer different advantages. For example, embodiments discussed herein include device structures and methods for fabrication of Schottky barrier diodes that address various existing challenges, as discussed above. The methods and Schottky diodes described herein, in some embodiments, are designed to have a high breakdown voltage, which provides for an increased operation voltage. Such devices may thus be suitable for a wider array of applications. In some embodiments, the higher breakdown voltage is achieved by adding one or more contact features into an isolation region, such as an STI region, between an anode and a cathode of the Schottky diode. The one or more contact features formed in the isolation region, which may be electrically coupled to the cathode of the Schottky diode, can be used to enlarge a depletion region and thereby increase a breakdown voltage of the device. Additional embodiments and advantages will be evident to those skilled in the art in possession of this disclosure.

Thus, one of the embodiments of the present disclosure described a method including providing a first isolation feature in a substrate, where the first isolation feature defines and isolates a cathode region of a Schottky barrier diode (SBD) from an anode region of the SBD. In some embodiments, the method further includes forming a patterned resist protective oxide (RPO) layer over the first isolation feature. Thereafter, the method further includes forming a first metal contact that extends through the patterned RPO layer and extends into the first isolation feature.

In another of the embodiments, discussed is a method including providing a substrate including a first isolation feature surrounding an anode region of a diode, a cathode region surrounding the first isolation feature, and a second isolation feature surrounding the cathode region. In some embodiments, the method further includes depositing a multi-layer dielectric stack over the anode region, the cathode region, and the first and second isolation features. In some examples, the method further includes patterning the multi-layer dielectric stack to remove portions of the multi-layer dielectric stack from over the anode region, the cathode region, and the second isolation feature, while the patterned multi-layer dielectric stack remains disposed over the first isolation feature. In some cases, the method further includes performing a multi-step etch process to the patterned multi-layer dielectric stack to form a plurality of openings that extend through the patterned multi-layer dielectric stack and extend into the first isolation feature on multiple sides of the anode region.

In yet another of the embodiments, discussed is a Schottky barrier device (SBD) including an isolation feature in a substrate, where the isolation feature defines and isolates a cathode region of the SBD from an anode region of the SBD. In some embodiments, the SBD further includes a patterned resist protective oxide (RPO) layer disposed over the isolation feature, and a metal contact that extends through the patterned RPO layer and extends into the isolation feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a first isolation feature in a substrate, wherein the first isolation feature defines and isolates a cathode region of a Schottky barrier diode (SBD) from an anode region of the SBD;
forming a patterned resist protective oxide (RPO) layer over the first isolation feature; and
forming a first metal contact that extends through the patterned RPO layer and extends into the first isolation feature.

2. The method of claim 1, wherein the first isolation feature surrounds the anode region of the SBD.

3. The method of claim 1, wherein the RPO layer includes a multi-layer dielectric stack.

4. The method of claim 1, wherein the RPO layer includes a first oxide layer, a nitride layer disposed over the first oxide layer, and a second oxide layer disposed over the nitride layer.

5. The method of claim 1, wherein forming the first metal contact comprises:
performing a three-step etch process to form an opening that extends through the patterned RPO layer and extends into the first isolation feature; and
depositing a metal layer within the opening to provide the first metal contact.

6. The method of claim 5, wherein the RPO layer includes a first oxide layer, a nitride layer disposed over the first oxide layer, and a second oxide layer disposed over the nitride layer, wherein a first step of the three-step etch process etches a portion of the second oxide layer, wherein a second step of the three-step etch process etches a portion of the nitride layer, and wherein a third step of the three-step etch process etches a portion of the first oxide layer and a portion of the first isolation feature to form the opening.

7. The method of claim 1, further comprising:
prior to forming the patterned RPO layer, forming an N+ region in the cathode region and a P+ region in the anode region; and
after forming the patterned RPO layer, forming a second metal contact that contacts the N+ region and a third metal contact that contacts the P+ region.

8. The method of claim 7, further comprising:
forming a first metal interconnect layer that electrically couples the first metal contact and the second metal contact; and
forming a second metal interconnect layer that electrically couples to the third metal contact.

9. The method of claim 2, further comprising forming a plurality of metal contacts that extend through the patterned RPO layer and extend into the first isolation feature, wherein the plurality of metal contacts surrounds the anode region of the SBD.

10. The method of claim 1, further comprising providing a second isolation feature in the substrate, wherein the second isolation feature surrounds the SBD.

11. A method, comprising:
providing a substrate including a first isolation feature surrounding an anode region of a diode, a cathode region surrounding the first isolation feature, and a second isolation feature surrounding the cathode region;
depositing a multi-layer dielectric stack over the anode region, the cathode region, and the first and second isolation features;
patterning the multi-layer dielectric stack to remove portions of the multi-layer dielectric stack from over the anode region, the cathode region, and the second isolation feature, while the patterned multi-layer dielectric stack remains disposed over the first isolation feature; and
performing a multi-step etch process to the patterned multi-layer dielectric stack to form a plurality of openings that extend through the patterned multi-layer dielectric stack and extend into the first isolation feature on multiple sides of the anode region.

12. The method of claim 11, further comprising:
prior to depositing the multi-layer dielectric stack, performing a first ion implantation process into the cathode region, the anode region, and through the first and second isolation features to form a high voltage N-well (HVNW);
performing a second ion implantation process into the cathode region to form an N-well region in the cathode region;
performing a third ion implantation process into the cathode region to form a plurality of N+ regions; and
performing a fourth ion implantation process into the anode region to form a plurality of P+ regions.

13. The method of claim 11, further comprising:
prior to performing the multi-step etch process, depositing an inter-layer dielectric (ILD) layer over the anode region, over the cathode region, over the patterned multi-layer dielectric stack disposed over the first isolation feature, and over the second isolation feature;
wherein a first step of the multi-step etch process etches the ILD layer over the patterned multi-layer dielectric stack and a topmost layer of the patterned multi-layer dielectric stack.

14. The method of claim 11, wherein the multi-layer dielectric stack includes a first oxide layer, a nitride layer disposed over the first oxide layer, and a second oxide layer disposed over the nitride layer.

15. The method of claim 11, further comprising:
depositing a metal layer within the plurality of openings to provide a first plurality of metal contacts that extend through the patterned multi-layer dielectric stack and extend into the first isolation feature on multiple sides of the anode region.

16. The method of claim 15, further comprising:
forming a first metal interconnect layer that electrically couples the first plurality of metal contacts to a second plurality of metal contacts in contact with a plurality of N+ regions in the cathode region of the diode.

17. A Schottky barrier device (SBD), comprising:
an isolation feature in a substrate, wherein the isolation feature defines and isolates a cathode region of the SBD from an anode region of the SBD;
a patterned resist protective oxide (RPO) layer disposed over the isolation feature; and
a metal contact that extends through the patterned RPO layer and extends into the isolation feature.

18. The SBD of claim 17, wherein the RPO layer includes a first oxide layer, a nitride layer disposed over the first oxide layer, and a second oxide layer disposed over the nitride layer.

19. The SBD of claim 17, further comprising:
a metal interconnect layer that electrically couples the metal contact to another metal contact in contact with an N+ region in the cathode region of the SBD.

20. The SBD of claim 17, wherein the metal contact extends into the isolation feature by a first distance, wherein a depth of the isolation feature is equal to a second distance, and wherein the first distance is in a range of between about 0.3-0.5 times the second distance.
